(19) United States
(12) Patent Application Publication
(10) Pub. No.: US 2026/0246203 A1
(43) Pub. Date: Aug. 20, 2026

(54) Shielded Connector Assembly With Frequency-Selective Slot Array

(71) Applicant: Skydio, Inc., San Mateo, CA (US)

(72) Inventors: Srishti Saraswat, Union City, CA (US); Kshitiz Nautiyal, Santa Clara, CA (US)

(21) Appl. No.: 19/543,980

(22) Filed: Feb. 19, 2026

Related U.S. Application Data
(60) Provisional application No. 63/760,311, filed on Feb. 19, 2025.

(51) Int. Cl. H01R 13/6581; H01R 12/51; H01R 12/70; H01R 13/6594; H01R 43/02; H05K 1/182

(52) U.S. Cl. CPC H01R 13/6581; H01R 12/51; H01R 12/7076; H01R 13/6594; H01R 43/0256; H05K 1/182; H05K 2201/10189; H05K 2203/043

(57) ABSTRACT

A shielded connector assembly comprising a high-speed connector housing and an outer conductive spatial shield configured to at least partially surround the housing. The outer conductive spatial shield includes a top wall and at least one side wall defining an interior cavity. Slot apertures are formed in the at least one side wall, arranged in a slot array and dimensioned such that at least one geometric parameter corresponds to a fraction of a wavelength of targeted electromagnetic interference frequencies, whereby the slot array functions as a frequency-selective structure that attenuates electromagnetic energy at the targeted frequencies. A bottom flange of the outer conductive spatial shield may be continuously soldered to a printed circuit board to establish a substantially continuous low-impedance ground path. At least one lanced feature extends into the interior cavity, configured to provide electrical engagement between the outer conductive spatial shield and the high-speed connector housing.

### CROSS-REFERENCE TO RELATED APPLICATIONS

This application is related to and claims the benefit of priority to U.S. Provisional Patent Application No. 63/760,311, titled “Connector Shield Design For EMI And Desense Mitigation And Related Methods,” filed February 19, 2025, which is hereby incorporated by reference in its entirety.

### FIELD OF INVENTION

The present disclosure relates to electromagnetic interference shielding for electronic connectors, and more particularly to a shielded connector assembly incorporating a frequency-selective slot array and continuous grounding structure for mitigating electromagnetic interference and receiver desensitization in high-speed connector applications. In particular, the disclosure relates to connector-scale shielding structures that integrate frequency-selective slot arrays with substantially continuous low-impedance grounding.

### BACKGROUND

High-speed electronic connectors, such as those conforming to Universal Serial Bus (USB), High-Definition Multimedia Interface (HDMI), DisplayPort, PCI Express (PCIe), and Mobile Industry Processor Interface (MIPI) standards, are widely deployed in modern electronic devices to facilitate rapid data transmission between components and peripheral devices. As data rates have increased to accommodate growing bandwidth demands, these connectors have become sources of electromagnetic emissions that can extend into radio frequency bands utilized by wireless communication systems. The electromagnetic energy radiated from high-speed connectors can couple into nearby antenna structures and receiver circuits, potentially degrading the performance of wireless subsystems operating in proximity to the connector.

Conventional approaches to electromagnetic interference mitigation in connector assemblies have included the use of metallic shields, ferrite components, conductive gaskets, and enhanced printed circuit board grounding techniques. Metallic shields surrounding connector housings provide a degree of electromagnetic containment, though such shields may include apertures, seams, or discontinuities that permit electromagnetic energy to escape at certain frequencies. The effectiveness of a conductive shield in attenuating electromagnetic radiation is influenced by the electrical continuity of the shield structure and the impedance of connections between the shield and a reference ground plane. Discrete grounding connections, such as individual tabs or pins soldered to a printed circuit board at spaced intervals, may introduce impedance variations along the shield perimeter that can affect shielding performance at higher frequencies.

Frequency selective surfaces represent a class of electromagnetic structures that exhibit filtering characteristics based on the geometry and arrangement of conductive or aperture elements within the surface. However, conventional frequency selective surface implementations are typically applied to planar enclosure panels or antenna structures and do not address impedance discontinuities or grounding continuity at connector-scale interfaces. Such structures can be configured to attenuate, reflect, or transmit electromagnetic energy at particular frequencies depending on the dimensional relationships between the surface features and the wavelengths of incident electromagnetic waves. The application of frequency selective principles to shielding structures presents opportunities for tailoring the electromagnetic response of a shield to address interference at specific frequency bands while maintaining other functional characteristics of the shield assembly.

The coexistence of high-speed digital interfaces and wireless communication systems within compact electronic devices continues to present design challenges related to electromagnetic compatibility. Approaches that address both the grounding characteristics and the frequency-selective behavior of connector shielding structures may provide benefits in managing electromagnetic interference and maintaining wireless receiver sensitivity in such environments.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a shielded connector assembly is provided. The shielded connector assembly comprises a high-speed connector housing. The shielded connector assembly further comprises an outer conductive spatial shield formed of conductive material and configured to at least partially surround the high-speed connector housing. The outer conductive spatial shield includes a top wall and at least one side wall defining an interior cavity. A plurality of slot apertures are formed in the at least one side wall of the outer conductive spatial shield. The plurality of slot apertures are arranged in a slot array and dimensioned such that at least one geometric parameter corresponds to a fraction of a wavelength of one or more targeted electromagnetic interference frequencies, whereby the slot array functions as a frequency-selective structure that attenuates electromagnetic energy at the one or more targeted electromagnetic interference frequencies. At least one lanced feature is formed from material of the outer conductive spatial shield and extends into the interior cavity. The at least one lanced feature is configured to provide electrical engagement between the outer conductive spatial shield and the high-speed connector housing disposed within the interior cavity.

According to other aspects of the present disclosure, the shielded connector assembly may include one or more of the following features. Each slot aperture may comprise a U-shaped slot having a slot length (L), a slot width (W), and a center-to-center spacing (S) relative to adjacent slot apertures. The slot length (L) may be selected to produce electromagnetic resonance at the one or more targeted electromagnetic interference frequencies. The shielded connector assembly may further comprise a metal web disposed between adjacent slot apertures, the metal web providing structural rigidity and an uninterrupted conductive path outside of a resonance band associated with the one or more targeted electromagnetic interference frequencies. The shielded connector assembly may further comprise a resilient grounding tab extending from a mating wall of the outer conductive spatial shield and configured to maintain electrical contact with a conductive surface of the high-speed connector housing. The at least one lanced feature may cooperate with the resilient grounding tab to maintain a low-impedance electrical connection between the outer conductive spatial shield and the high-speed connector housing. The shielded connector assembly may further comprise a retention lance formed from material of the outer conductive spatial shield and configured to mechanically secure the outer conductive spatial shield relative to the high-speed connector housing. The shielded connector assembly may further comprise a folded hem along a lower perimeter of the outer conductive spatial shield, the folded hem providing structural stiffness and enhanced solder-wicking capability when mounted to a printed circuit board. The shielded connector assembly may further comprise a bottom flange extending along a lower edge of the outer conductive spatial shield and configured for mechanical and electrical attachment to a printed circuit board. The shielded connector assembly may further comprise at least one alignment feature extending downward from the bottom flange and configured to position the shielded connector assembly relative to a printed circuit board.

According to another aspect of the present disclosure, a shielded connector assembly is provided. The shielded connector assembly comprises a high-speed connector housing. The shielded connector assembly further comprises an outer conductive spatial shield formed of conductive material and configured to at least partially surround the high-speed connector housing. A plurality of slot apertures are formed in the outer conductive spatial shield and arranged in a slot array dimensioned to function as a frequency-selective structure that attenuates electromagnetic energy at one or more targeted electromagnetic interference frequencies. A bottom flange extends along a lower perimeter of the outer conductive spatial shield. The bottom flange is configured to be continuously soldered to a ground reference of a printed circuit board to establish a substantially continuous, low-impedance electrical ground path around at least a portion of the outer conductive spatial shield. Common-mode currents induced on the outer conductive spatial shield are preferentially shunted to the ground reference through the substantially continuous, low-impedance electrical ground path while the slot array attenuates electromagnetic energy at the one or more targeted electromagnetic interference frequencies.

According to other aspects of the present disclosure, the shielded connector assembly may include one or more of the following features. The bottom flange may be configured to form a metallurgical bond to ground pads of the printed circuit board during a reflow soldering process. Impedance variation along an interface between the bottom flange and the printed circuit board may be minimized to suppress formation of resonant leakage paths at frequencies above 1 GHz. Each slot aperture may comprise a U-shaped slot having a slot length selected based on a fraction of a wavelength of the one or more targeted electromagnetic interference frequencies. The slot array may be configured to produce a frequency-selective response characterized by a notch in shielding effectiveness at a notch frequency corresponding to an engineered resonance of the slot array. The one or more targeted electromagnetic interference frequencies may comprise frequencies between approximately 2.4 GHz and 6 GHz. The high-speed connector housing may comprise a connector selected from the group consisting of a Universal Serial Bus connector, an HDMI connector, a DisplayPort connector, a PCI Express connector, and a MIPI interface connector.

According to another aspect of the present disclosure, a printed circuit board assembly is provided. The printed circuit board assembly comprises a printed circuit board including a ground plane. The printed circuit board assembly further comprises a high-speed connector housing mounted to the printed circuit board and including a plurality of electrical terminals. The printed circuit board assembly further comprises an outer conductive spatial shield at least partially surrounding the high-speed connector housing. The outer conductive spatial shield includes a plurality of slot apertures arranged in a slot array dimensioned to attenuate electromagnetic energy at one or more predetermined electromagnetic interference frequencies. The outer conductive spatial shield further includes a bottom flange continuously soldered to the ground plane of the printed circuit board to establish a substantially continuous, low-impedance ground path for the outer conductive spatial shield. The slot array and the substantially continuous, low-impedance ground path cooperate to suppress electromagnetic interference within the printed circuit board assembly.

According to other aspects of the present disclosure, the printed circuit board assembly may include one or more of the following features. Each slot aperture may comprise a U-shaped slot having a slot length selected to produce electromagnetic resonance at the one or more predetermined electromagnetic interference frequencies. A metal web may be disposed between adjacent slot apertures to provide structural rigidity and an uninterrupted conductive path outside of a resonance band associated with the one or more predetermined electromagnetic interference frequencies.

According to another aspect of the present disclosure, a method of mitigating electromagnetic interference in a high-speed connector is provided. The method comprises providing an outer conductive spatial shield configured to at least partially surround a high-speed connector housing. The method further comprises forming a plurality of slot apertures in the outer conductive spatial shield. The plurality of slot apertures are dimensioned to function as frequency-selective elements that attenuate electromagnetic energy at one or more targeted electromagnetic interference frequencies. The method further comprises continuously soldering a bottom flange of the outer conductive spatial shield to a ground reference of a printed circuit board to establish a substantially continuous, low-impedance ground path, whereby common-mode currents induced on the outer conductive spatial shield are shunted to the ground reference while electromagnetic energy at the one or more targeted electromagnetic interference frequencies is attenuated by the slot apertures.

According to other aspects of the present disclosure, the method may include one or more of the following features. Forming the plurality of slot apertures may comprise forming U-shaped slots having a slot length selected based on a fraction of a wavelength of the one or more targeted electromagnetic interference frequencies. The method may further comprise forming at least one lanced feature from material of the outer conductive spatial shield and bending the at least one lanced feature inwardly to provide electrical engagement between the outer conductive spatial shield and the high-speed connector housing.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates an isometric view of a shielded connector assembly with an outer conductive spatial shield, according to aspects of the present disclosure.

FIG. 2 illustrates an isometric view of a shielded connector assembly with a slot array, according to an embodiment.

FIG. 3 illustrates an enlarged view of a frequency-selective region of the outer conductive spatial shield of FIG. 1, according to aspects of the present disclosure.

FIG. 4 illustrates a frequency-response plot showing shielding effectiveness as a function of frequency, according to an embodiment.

FIG. 5 illustrates a bottom perspective view of a shielded connector assembly, according to aspects of the present disclosure.

FIG. 6 illustrates a perspective view of a shielded connector assembly with a folded hem, according to an embodiment.

FIG. 7 illustrates a printed circuit board assembly including a shielded high-speed connector, according to aspects of the present disclosure.

FIG. 8 illustrates a flowchart for a method of mitigating electromagnetic interference in a high-speed connector, according to an embodiment.

FIG. 9 illustrates a flowchart for a method of mitigating electromagnetic interference using U-shaped slots, according to aspects of the present disclosure.

FIG. 10 illustrates a flowchart for a method of mitigating electromagnetic interference using lanced features, according to an embodiment.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

The present disclosure relates to a shielded connector assembly configured to address electromagnetic interference (EMI) and receiver desensitization (desense) challenges encountered in high-speed connector applications. Unlike conventional connector shields that rely on discrete grounding tabs, the embodiments described herein provide either multiple distributed internal engagement points or a substantially continuous soldered perimeter ground interface. High-speed connectors, such as those used for USB 3.0, USB 4.0, HDMI, PCIe, and MIPI interfaces, may generate substantial electromagnetic noise during operation. Such noise may radiate from the connector structure and couple into nearby wireless receivers, including Wi-Fi, Bluetooth, LTE, and GPS antennas, thereby reducing receiver sensitivity and degrading wireless performance. The shielded connector assembly described herein addresses these challenges through an integrated approach that combines frequency-selective filtering with robust grounding.

In some cases, the shielded connector assembly includes an outer conductive spatial shield configured to at least partially surround a high-speed connector housing. The outer conductive spatial shield may be formed of a conductive material, such as a metal or metal alloy, and may define an interior cavity sized to receive the high-speed connector housing. The outer conductive spatial shield may include a top wall and at least one side wall that together provide electromagnetic containment around the high-speed connector housing.

The outer conductive spatial shield may include a plurality of slot apertures formed in at least one wall of the shield structure. The slot apertures may be arranged in a slot array and may be dimensioned such that at least one geometric parameter corresponds to a fraction of a wavelength of one or more targeted electromagnetic interference frequencies. In this manner, the slot array may function as a frequency-selective structure that attenuates electromagnetic energy at the targeted frequencies. The slot apertures may leverage electromagnetic resonance to reflect or absorb EMI at the targeted frequencies, thereby acting as an integrated band-stop filter for those frequencies. Outside of the targeted resonance band, the outer conductive spatial shield may behave as a substantially continuous conductive barrier that blocks electromagnetic interference at other frequencies.

The shielded connector assembly may further include at least one lanced feature formed from material of the outer conductive spatial shield. The lanced feature may extend into the interior cavity and may be configured to provide electrical engagement between the outer conductive spatial shield and the high-speed connector housing disposed within the interior cavity. In some cases, the lanced feature may cooperate with a resilient grounding tab to maintain a low-impedance electrical connection between the outer conductive spatial shield and the high-speed connector housing. The electrical engagement provided by the lanced feature and the resilient grounding tab may reduce impedance discontinuities and may suppress common-mode noise that could otherwise radiate from the connector structure.

The shielded connector assembly may include a bottom flange extending along a lower perimeter of the outer conductive spatial shield. The bottom flange may be configured to be continuously soldered to a ground reference of a printed circuit board to establish a substantially continuous, low-impedance electrical ground path around at least a portion of the outer conductive spatial shield. By soldering the bottom flange continuously to the ground reference, impedance variation along the interface between the outer conductive spatial shield and the printed circuit board may be minimized. Common-mode currents induced on the outer conductive spatial shield may be preferentially shunted to the ground reference through the substantially continuous, low-impedance electrical ground path, rather than radiating as electromagnetic interference.

The combination of the frequency-selective slot array and the substantially continuous, low-impedance ground path may provide a synergistic approach to EMI mitigation. The substantially continuous ground path reduces phase distortion and parasitic inductance along the shield perimeter, thereby stabilizing the resonant characteristics of the slot array. The slot array may attenuate electromagnetic energy at targeted frequencies through resonant filtering, while the continuous ground connection may suppress broadband common-mode noise by providing a low-impedance return path to the ground reference. The integration of these two approaches within a single outer conductive spatial shield may address both conducted and radiated EMI mechanisms, thereby reducing desense of nearby wireless receivers and improving electromagnetic compatibility performance of the shielded connector assembly.

The shielded connector assembly may provide suppression of common-mode currents through low-impedance grounding. When the bottom flange of the outer conductive spatial shield is continuously soldered to a ground reference of a printed circuit board, a substantially continuous, low-impedance electrical ground path may be established around at least a portion of the outer conductive spatial shield. Common-mode currents induced on the outer conductive spatial shield during high-speed data transmission may be preferentially shunted to the ground reference through this low-impedance path, rather than radiating as electromagnetic interference or coupling into nearby wireless receivers. The continuous soldering approach may eliminate impedance discontinuities that could otherwise create resonant leakage paths at high frequencies, thereby maintaining effective shielding performance across a broad frequency range.

The shielded connector assembly may provide targeted attenuation of electromagnetic energy at specific interference frequencies through the frequency-selective slot array. The slot apertures may be dimensioned such that geometric parameters, including slot length, slot width, and center-to-center spacing, correspond to a fraction of a wavelength of one or more targeted electromagnetic interference frequencies. At these targeted frequencies, the slot array may exhibit electromagnetic resonance that attenuates or reflects electromagnetic energy, producing a frequency-selective response characterized by a notch in shielding effectiveness at the targeted frequencies. Outside of the resonance band, the outer conductive spatial shield may continue to function as a substantially continuous conductive barrier. In some cases, the targeted electromagnetic interference frequencies may comprise frequencies between approximately 2.4 GHz and 6 GHz, which may correspond to frequency bands used by wireless communication systems such as Wi-Fi and Bluetooth that are susceptible to interference from high-speed connectors.

The shielded connector assembly may provide improved signal integrity for high-speed data transmission. By minimizing ground impedance and containing electromagnetic interference at the connector structure, the shielded connector assembly may reduce ground bounce and radiation that could otherwise perturb signal lines within the high-speed connector housing. The suppression of common-mode noise through low-impedance grounding may reduce noise coupling back into signal pairs, which may otherwise cause mode conversion and degrade differential signal quality. In some cases, the improved electromagnetic environment provided by the shielded connector assembly may contribute to lower bit error rates in high-speed data links operating at multi-gigabit data rates.

The shielded connector assembly may provide enhanced mechanical retention and board alignment. The bottom flange, alignment features, and rear mounting tabs may cooperate to position the shielded connector assembly relative to a printed circuit board and to secure the shielded connector assembly during operation. The continuous soldering of the bottom flange to the printed circuit board may provide both electrical grounding and mechanical attachment, creating a robust connection that may withstand mechanical stresses including connector mating cycles and vibration. The alignment features may engage corresponding apertures in the printed circuit board to ensure proper positioning prior to soldering, while the rear mounting tabs may provide additional retention and grounding at opposing ends of the outer conductive spatial shield.

The shielded connector assembly may facilitate compliance with electromagnetic compatibility regulations. By reducing radiated emissions at targeted frequencies through the frequency-selective slot array and by suppressing common-mode currents through the substantially continuous, low-impedance ground path, the shielded connector assembly may help electronic devices meet electromagnetic compatibility requirements established by regulatory bodies. The combination of frequency-selective filtering and continuous grounding may reduce emission peaks in the electromagnetic spectrum that could otherwise exceed regulatory limits, thereby improving compliance margins without requiring additional shielding enclosures or filtering components external to the connector structure.

The combination of frequency-selective filtering and continuous grounding may provide synergistic EMI mitigation within the shielded connector assembly. The frequency-selective slot array may address radiated electromagnetic interference at specific targeted frequencies by producing resonant attenuation, while the substantially continuous, low-impedance ground path may address broadband common-mode noise by providing a low-impedance return path to the ground reference. The robust grounding provided by the continuous soldering approach may also enhance the effectiveness of the frequency-selective slot array by establishing a stable electromagnetic reference plane for the outer conductive spatial shield. In this manner, the two approaches may complement each other to provide comprehensive EMI mitigation that addresses both frequency-specific interference and broadband noise mechanisms. The integration of both approaches within a single outer conductive spatial shield may provide a compact solution that does not require additional filtering components or separate grounding structures, thereby reducing complexity and cost while improving electromagnetic compatibility performance.

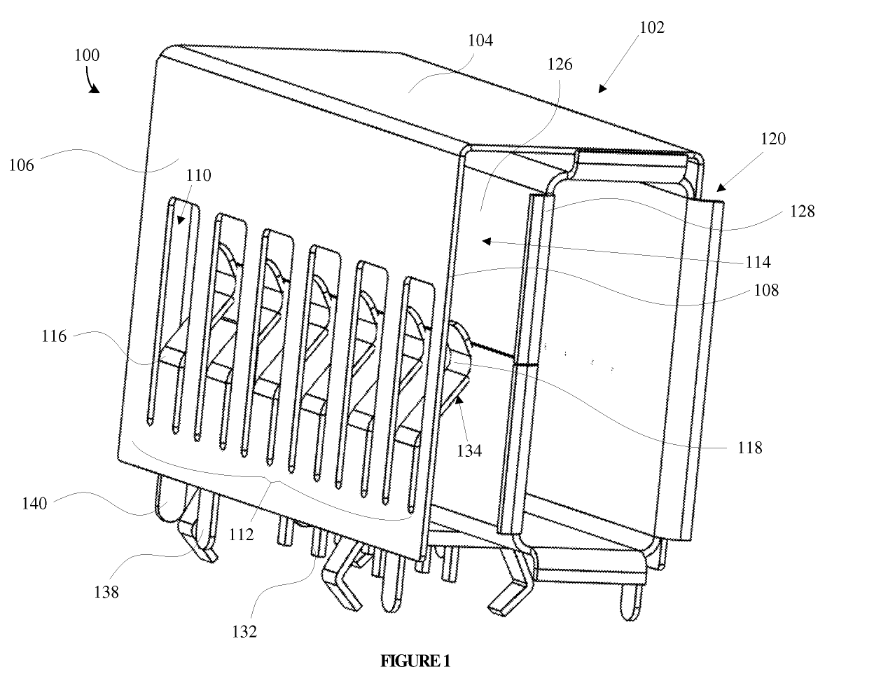

Referring to FIG. 1, a shielded connector assembly 100 includes an outer conductive spatial shield 102 configured to at least partially surround a high-speed connector housing 120. The outer conductive spatial shield 102 may be formed of conductive material and may define an interior cavity 114 sized to receive the high-speed connector housing 120. The outer conductive spatial shield 102 includes a top wall 104, at least one side wall 106, and a mating wall 108 that together define the interior cavity 114. In the configuration shown in FIG. 1, the top wall 104 extends longitudinally over the high-speed connector housing 120, while the side wall 106 and the mating wall 108 provide lateral and forward enclosure of the high-speed connector housing 120 within the interior cavity 114.

The outer conductive spatial shield 102 may be formed from stamped sheet metal such as copper alloy, brass, or stainless steel. In some cases, the outer conductive spatial shield 102 may be formed from a conductive composite material or from conductive polymer material. The outer conductive spatial shield 102 may be plated with tin, nickel, or silver flash to enhance conductivity and corrosion resistance. In some cases, the outer conductive spatial shield 102 may be a one-piece wraparound shield that surrounds the high-speed connector housing 120. In other cases, the outer conductive spatial shield 102 may comprise multiple pieces that assemble around the high-speed connector housing 120.

With continued reference to FIG. 1, a plurality of slot apertures 110 are formed in the side wall 106 of the outer conductive spatial shield 102. The plurality of slot apertures 110 are arranged in a slot array 112 and are dimensioned such that at least one geometric parameter corresponds to a fraction of a wavelength of one or more targeted electromagnetic interference frequencies. In this manner, the slot array 112 functions as a frequency-selective structure that attenuates electromagnetic energy at the one or more targeted electromagnetic interference frequencies. The slot apertures 110 are elongated openings extending through the material of the side wall 106 and may provide spatial filtering while maintaining structural integrity of the outer conductive spatial shield 102.

At least one lanced feature 116 is formed from material of the outer conductive spatial shield 102 and extends into the interior cavity 114. The lanced feature 116 is configured to provide electrical engagement between the outer conductive spatial shield 102 and the high-speed connector housing 120 disposed within the interior cavity 114. As shown in FIG. 1, each slot aperture 110 may include an associated lanced feature 116 that may be bent inwardly toward the high-speed connector housing 120 to establish electrical contact between the outer conductive spatial shield 102 and the high-speed connector housing 120.

The shielded connector assembly 100 further includes a resilient grounding tab 118 extending from the mating wall 108 of the outer conductive spatial shield 102. The resilient grounding tab 118 is configured to maintain electrical contact with a conductive surface of the high-speed connector housing 120. In some cases, the lanced feature 116 may cooperate with the resilient grounding tab 118 to maintain a low-impedance electrical connection between the outer conductive spatial shield 102 and the high-speed connector housing 120, as described previously.

As further shown in FIG. 1, a retention lance 134 is formed from material of the outer conductive spatial shield 102 and is configured to mechanically secure the outer conductive spatial shield 102 relative to the high-speed connector housing 120. The retention lance 134 may extend inwardly from the side wall 106 and may engage a corresponding feature of the high-speed connector housing 120 to provide mechanical retention.

The shielded connector assembly 100 includes one or more alignment features 138 configured to position the shielded connector assembly 100 relative to a printed circuit board. The alignment features 138 may extend downwardly from a lower portion of the outer conductive spatial shield 102 and may engage corresponding apertures in the printed circuit board to ensure proper positioning during assembly. At least one rear mounting tab 140 extends from the outer conductive spatial shield 102 and is configured for mechanical and electrical attachment to the printed circuit board. The rear mounting tab 140 may provide additional board retention and grounding when soldered to conductive pads on the printed circuit board.

The high-speed connector housing 120 disposed within the interior cavity 114 includes a side wall 126 and a mating wall 128. A plurality of electrical terminals 132 extend downwardly from the high-speed connector housing 120 for connection to a printed circuit board. The electrical terminals 132 may be configured for insertion into or soldering onto corresponding pads of the printed circuit board. The high-speed connector housing 120 may comprise a connector selected from the group consisting of a Universal Serial Bus connector, an HDMI connector, a DisplayPort connector, a PCI Express connector, and a MIPI interface connector.

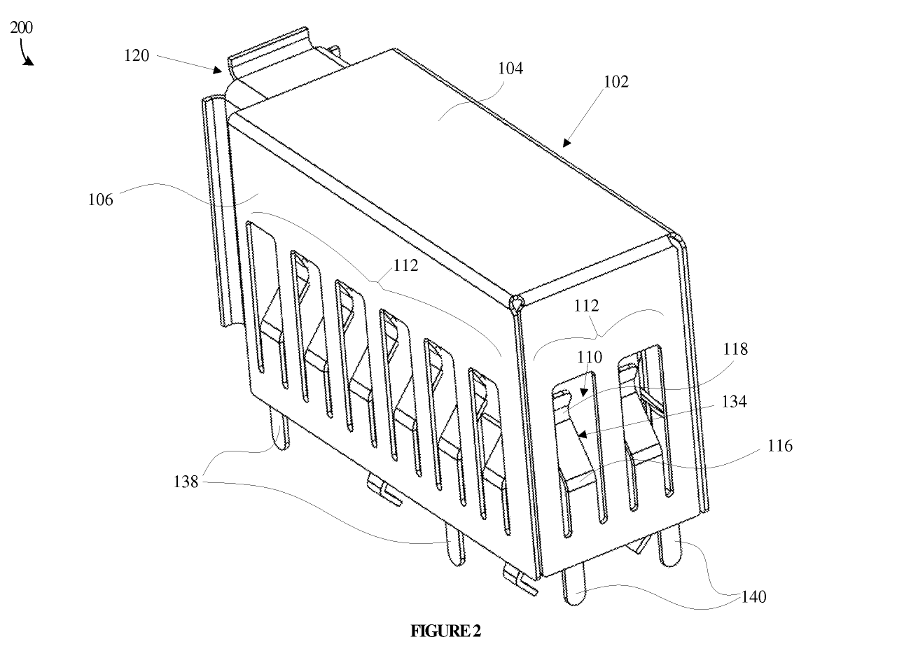

Referring to FIG. 2, a shielded connector assembly 200 includes the outer conductive spatial shield 102 disposed over the high-speed connector housing 120. The outer conductive spatial shield 102 includes the top wall 104 and opposing side walls 106, which together form an enclosed structure around the high-speed connector housing 120. In the configuration shown in FIG. 2, the outer conductive spatial shield 102 defines a plurality of slot apertures 110 arranged in one or more slot arrays 112 along the side walls 106.

Each slot aperture 110 extends vertically through the side wall 106 and includes an inwardly formed lanced feature 116. The lanced features 116 may be formed by partial stamping (lancing) and bending portions of the shield material. The lanced features 116 are bent inwardly toward the high-speed connector housing 120 and are configured to provide electrical engagement between the outer conductive spatial shield 102 and the high-speed connector housing 120.

With continued reference to FIG. 2, the lanced features 116 may cooperate with the resilient grounding tab 118 to maintain a low-impedance electrical connection between the outer conductive spatial shield 102 and the high-speed connector housing 120, as described previously. The cooperation between the lanced features 116 and the resilient grounding tab 118 may establish multiple points of electrical contact around the high-speed connector housing 120, thereby reducing impedance discontinuities and providing continuous electrical coupling between the outer conductive spatial shield 102 and the high-speed connector housing 120.

The retention lance 134 extends from the outer conductive spatial shield 102 and is configured to mechanically secure the outer conductive spatial shield 102 relative to the high-speed connector housing 120. The retention lance 134 may engage a corresponding feature of the high-speed connector housing 120 to provide mechanical retention that maintains the positional relationship between the outer conductive spatial shield 102 and the high-speed connector housing 120 during operation and connector mating cycles.

As further shown in FIG. 2, alignment features 138 extend downwardly from a lower portion of the outer conductive spatial shield 102 and are configured to position the shielded connector assembly 200 relative to a printed circuit board. The alignment features 138 may engage corresponding apertures in the printed circuit board to ensure proper positioning of the shielded connector assembly 200 during assembly. Rear mounting tabs 140 extend from the outer conductive spatial shield 102 and are configured for mechanical and electrical attachment to corresponding pads or apertures of the printed circuit board. The rear mounting tabs 140 may provide additional board retention and grounding when soldered or otherwise affixed to conductive pads on the printed circuit board.

In the assembled configuration shown in FIG. 2, the slot arrays 112 provide controlled apertures in the outer conductive spatial shield 102 while the lanced features 116 and the resilient grounding tab 118 ensure continuous electrical coupling between the outer conductive spatial shield 102 and the high-speed connector housing 120. The combined structure of the shielded connector assembly 200 provides mechanical retention through the retention lance 134, board alignment through the alignment features 138, and enhanced electromagnetic performance through the frequency-selective slot arrays 112 and the low-impedance electrical connections established by the lanced features 116 and the resilient grounding tab 118.

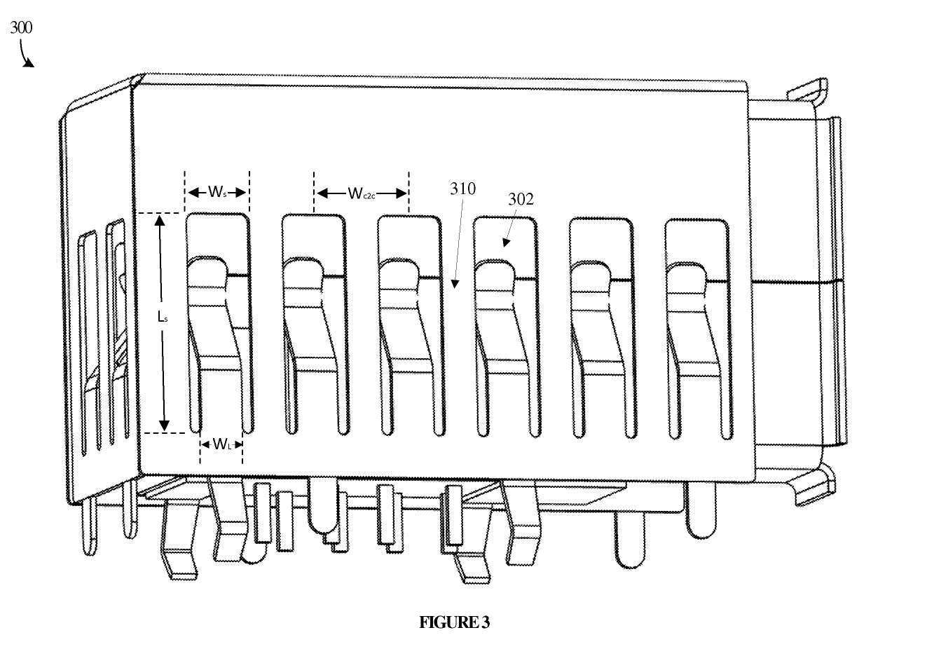

Referring to FIG. 3, an enlarged view of a frequency-selective region 300 of the outer conductive spatial shield is shown. The frequency-selective region 300 comprises a patterned portion of the shield wall incorporating a plurality of frequency-tuned slots. The frequency-selective region 300 includes multiple individual U-shaped slots 302, each U-shaped slot 302 representing a single instance of a slot aperture formed through the conductive shield material. The U-shaped slots 302 are arranged in a generally linear array along the shield surface.

Each U-shaped slot 302 is characterized by geometric parameters including a slot length (L), a slot width (W), and a center-to-center spacing (S) relative to adjacent slot apertures. As shown in FIG. 3, the slot length LS is measured from the upper closed end of the U-shape to the lower terminal ends of the slot legs. The slot width WL represents the lateral separation between the two parallel legs of the U-shaped slot 302. The center-to-center spacing WC2C defines the pitch between adjacent U-shaped slots 302, measured from the centerline of one slot to the centerline of the next.

The slot length (L) is selected to produce electromagnetic resonance at one or more targeted electromagnetic interference frequencies. The slot length may correspond to a fraction of a wavelength of the targeted electromagnetic interference frequencies, such that the U-shaped slots 302 exhibit resonant behavior at those frequencies. In some embodiments, the slot length corresponds to approximately one-half of an effective wavelength at the targeted frequency when accounting for conductive boundary conditions of the shield. In some cases, the slot length may be approximately 50-60 mm to target the 2.4 GHz frequency band. In other cases, the slot length may be approximately 25 mm to target the 5 GHz frequency band. The slot width may be approximately 1-2 mm to permit airflow while blocking GHz frequencies.

With continued reference to FIG. 3, a metal web 310 is disposed between adjacent slot apertures. The metal web 310 comprises a remaining conductive portion of the shield material between adjacent U-shaped slots 302. The metal web 310 provides structural rigidity to the shield body and mechanical continuity across the frequency-selective region 300. The metal web 310 also provides an uninterrupted conductive path for grounding and current return outside of a resonance band associated with the one or more targeted electromagnetic interference frequencies. In some cases, the outer conductive spatial shield may include ribs of metal between slots to provide reinforcement and maintain mechanical strength.

In operation, the array of U-shaped slots 302 within the frequency-selective region 300 collectively functions as a spatial filter. The geometric parameters including slot length, slot width, and center-to-center spacing are engineered to produce a desired resonance response that attenuates electromagnetic energy at selected frequencies while preserving mechanical stability and overall shielding effectiveness of the surrounding conductive structure.

The slot apertures may be formed in alternative geometric configurations. In some cases, the slot apertures may be formed as rectangular slots rather than U-shaped slots, providing an alternative geometric configuration for the frequency-selective elements. In some cases, the slot apertures may be formed as cross-shaped slots to control polarization or bandwidth of filtering for multi-band EMI mitigation. In some cases, the slot apertures may be formed as ring slots or concentric ring patterns to achieve multi-band rejection of electromagnetic interference.

The slot apertures may be configured to accommodate physical space constraints. In some cases, the slot apertures may be meandered or inductively loaded to electrically lengthen them within a smaller physical area when targeting lower frequencies. The slot apertures may be staggered in arrangement to maintain mechanical strength while providing the frequency-selective filtering function. In some cases, the slot array may be arranged in a lattice or grille pattern that provides structural robustness while allowing air passage for ventilation.

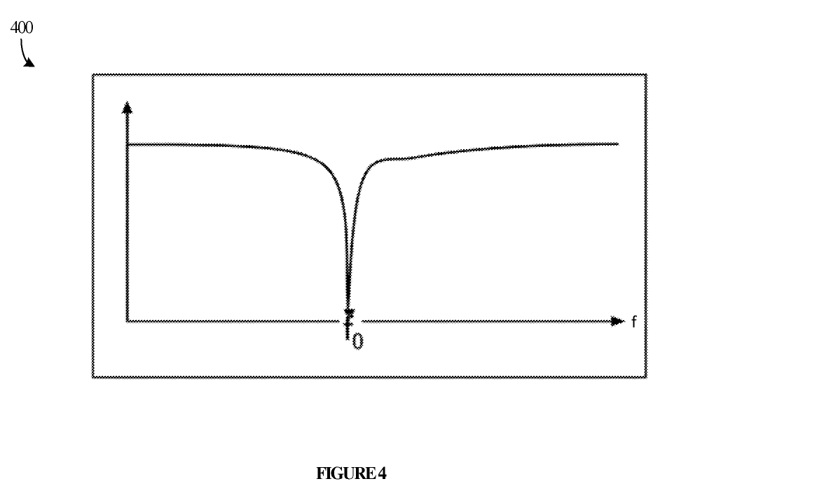

Referring to FIG. 4, an inset frequency-response plot 400 illustrates shielding effectiveness as a function of frequency for the frequency-selective region of the outer conductive spatial shield. The inset frequency-response plot 400 includes a vertical axis representing shielding effectiveness and a horizontal axis representing frequency f. A response curve extends across the inset frequency-response plot 400, maintaining a relatively high shielding effectiveness level across most of the frequency spectrum.

The slot array is configured to produce a frequency-selective response characterized by a notch in shielding effectiveness at a notch frequency f₀ corresponding to an engineered resonance of the slot array. The notch depth may correspond to at least 10 dB attenuation relative to adjacent frequency regions in some embodiments. As shown in FIG. 4, a pronounced notch appears in the response curve at the notch frequency f₀, representing a sharp dip in shielding effectiveness at that specific frequency. The notch frequency f₀ corresponds to the engineered resonance of the slot array formed in the outer conductive spatial shield, as described previously with reference to the U-shaped slots and the frequency-selective region.

The position of the notch frequency f₀ along the frequency axis is determined by the geometric parameters of the slot apertures, including slot length, slot width, and center-to-center spacing. As described previously, the slot length (L) is selected to produce electromagnetic resonance at one or more targeted electromagnetic interference frequencies. The slot width (W) affects impedance characteristics and bandwidth of the filtering response. The center-to-center spacing (S) governs mutual electromagnetic coupling between adjacent slot apertures and contributes to the overall frequency response of the slot array.

With continued reference to FIG. 4, outside the resonance region surrounding the notch frequency f₀, the response curve returns to a higher shielding effectiveness level. This behavior indicates broadband conductive shielding behavior of the remaining metal structure of the outer conductive spatial shield. At frequencies below and above the resonance band, the slot apertures are sub-wavelength in size, and the outer conductive spatial shield behaves as a substantially continuous conductive barrier that blocks electromagnetic interference.

The one or more targeted electromagnetic interference frequencies may comprise frequencies between approximately 2.4 GHz and 6 GHz. In some cases, the slot array may be configured to target the 2.4 GHz frequency band used by Wi-Fi and Bluetooth wireless communication systems. In some cases, the slot array may be configured to target the 5 GHz frequency band used by Wi-Fi wireless communication systems. The depth and bandwidth of the notch in the inset frequency-response plot 400 reflect the magnitude and selectivity of attenuation at the targeted interference frequency.

In some cases, the slot array may be configured to target cellular frequency bands in the 700-900 MHz range. In some cases, the slot array may be configured to target LTE frequency bands between 700 MHz and 2 GHz. The geometric parameters of the slot apertures may be adjusted to shift the notch frequency f₀ to correspond to these lower frequency bands, with longer slot lengths used to achieve resonance at lower frequencies.

The slot array may include multiple different slot configurations to provide multi-band EMI mitigation targeting different frequency bands simultaneously. In some cases, a first set of slot apertures may be dimensioned to target the 2.4 GHz frequency band while a second set of slot apertures may be dimensioned to target the 5 GHz frequency band. In such configurations, the inset frequency-response plot 400 may exhibit multiple notches at different frequencies corresponding to the engineered resonances of the different slot configurations. The multi-band approach may address interference from multiple wireless communication systems operating at different frequencies within the same electronic device.

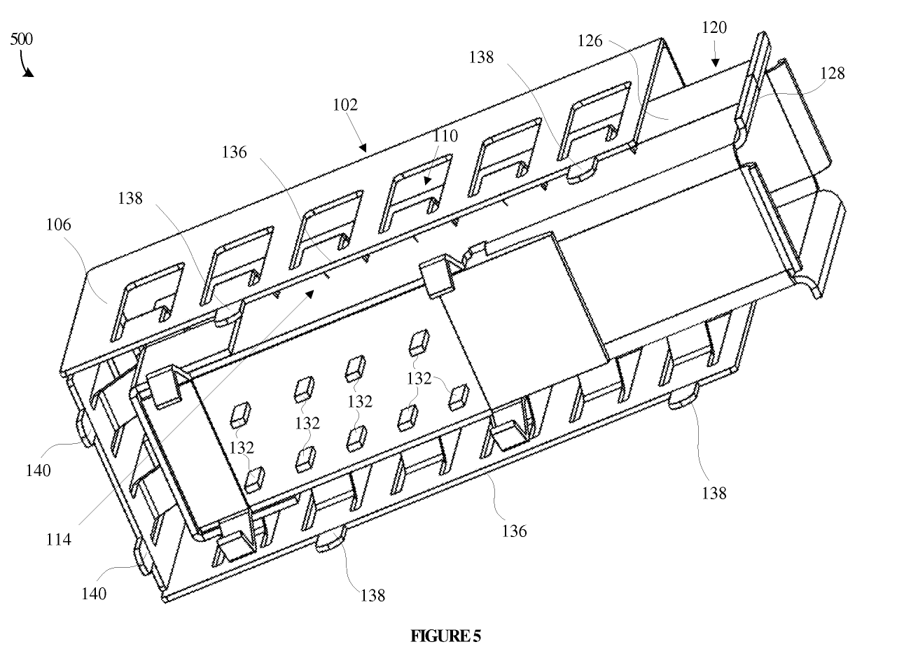

Referring to FIG. 5, a shielded connector assembly 500 is shown in a bottom perspective view, illustrating the relationship between the outer conductive spatial shield 102 and the high-speed connector housing 120 within the interior cavity 114. The outer conductive spatial shield 102 includes opposing side walls 106 and a plurality of slot apertures 110 formed along upper sidewall regions. The slot apertures 110 are arranged in a linear array and correspond to frequency-selective slot structures configured to provide spatial filtering while maintaining structural integrity, as described previously.

The shielded connector assembly 500 includes a bottom flange 136 extending along lower edges of the outer conductive spatial shield 102. The bottom flange 136 extends longitudinally along a lower perimeter of the outer conductive spatial shield 102 and is configured for mechanical and electrical attachment to a printed circuit board. The bottom flange 136 is configured to be continuously soldered to a ground reference of the printed circuit board to establish a substantially continuous, low-impedance electrical ground path around at least a portion of the outer conductive spatial shield 102.

With continued reference to FIG. 5, the bottom flange 136 may be configured to form a metallurgical bond to ground pads of the printed circuit board during a reflow soldering process. In some cases, the bottom flange 136 may include perforations or dimples to assist solder flow and ensure solder wicks around the tabs fully during assembly. The perforations or dimples may facilitate reliable solder joints along the interface between the bottom flange 136 and the printed circuit board. In some cases, the bottom flange 136 may be through-hole soldered or wave-soldered continuously to the printed circuit board as an alternative to surface mount reflow soldering.

Impedance variation along an interface between the bottom flange 136 and the printed circuit board may be minimized to suppress formation of resonant leakage paths at frequencies above 1 GHz. In contrast, discrete solder tabs separated by gaps may create periodic impedance discontinuities capable of supporting unintended slot-antenna resonances at high frequencies. By soldering the bottom flange 136 continuously to the ground reference, the substantially continuous, low-impedance electrical ground path may eliminate impedance discontinuities that could otherwise create resonant leakage paths at high frequencies. Common-mode currents induced on the outer conductive spatial shield 102 may be preferentially shunted to the ground reference through the substantially continuous, low-impedance electrical ground path while the slot array attenuates electromagnetic energy at the one or more targeted electromagnetic interference frequencies.

As further shown in FIG. 5, at least one alignment feature 138 extends downward from the bottom flange 136 and is configured to position the shielded connector assembly 500 relative to a printed circuit board. A plurality of alignment features 138 extend downward from the bottom flange 136 and may engage corresponding apertures in the printed circuit board to ensure proper positioning of the shielded connector assembly 500 during assembly. At opposing ends of the outer conductive spatial shield 102, rear mounting tabs 140 extend downward and outward, providing additional board retention and grounding when soldered or otherwise affixed to conductive pads on the printed circuit board.

The high-speed connector housing 120 disposed within the interior cavity 114 includes a side wall 126 and a mating wall 128. A plurality of electrical terminals 132 extend downward from the high-speed connector housing 120 for insertion into or soldering onto corresponding pads of the printed circuit board. In the configuration shown in FIG. 5, the outer conductive spatial shield 102 substantially surrounds the high-speed connector housing 120 while maintaining electrical engagement and mechanical retention.

The bottom perspective view of FIG. 5 illustrates the integrated relationship between the frequency-selective slot apertures 110 formed in the outer conductive spatial shield 102, the grounding and structural bottom flange 136, the alignment features 138, the rear mounting tabs 140, and the electrical terminals 132 of the high-speed connector housing 120. The combination of the slot array and the substantially continuous, low-impedance ground path established by the bottom flange 136 may cooperate to suppress electromagnetic interference within the shielded connector assembly 500, as described previously. The shielded connector assembly 500 forms a compact, mechanically robust, and electromagnetically controlled assembly configured for printed circuit board mounting and enhanced EMI and desense mitigation.

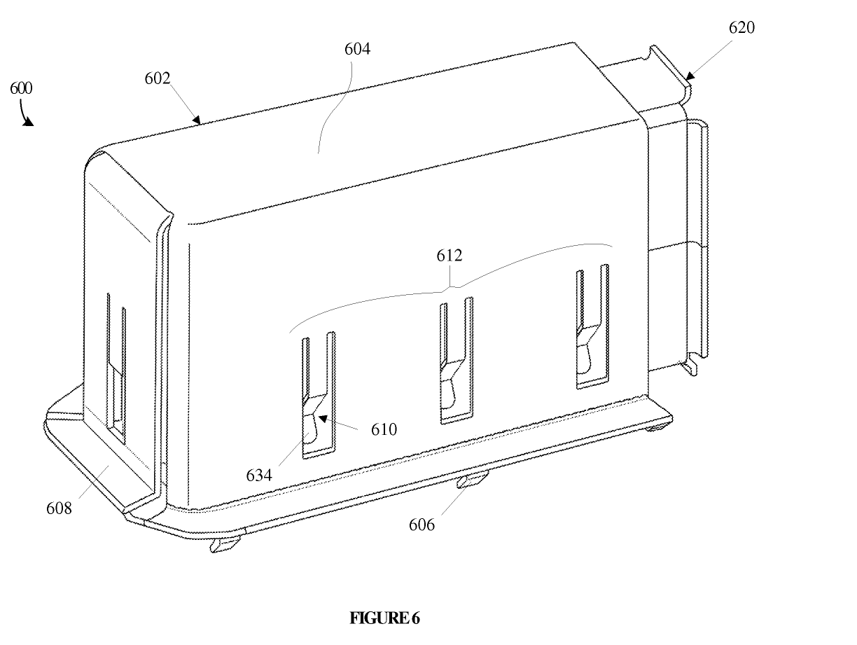

Referring to FIG. 6, a shielded connector assembly 600 includes an outer conductive spatial shield 602 surrounding an internal connector body. The outer conductive spatial shield 602 includes a top wall 604 extending longitudinally over the connector and opposing side walls that define an enclosed structure. The outer conductive spatial shield 602 is formed from a conductive material and is configured to provide electromagnetic containment and frequency-selective filtering. A corner edge 620 is visible at an upper portion of the outer conductive spatial shield 602 where the top wall 604 meets a side wall.

A plurality of slot apertures 610 are formed in at least one side wall of the outer conductive spatial shield 602. The slot apertures 610 are arranged in a slot array 612 that spans a defined region of the shield side wall. The slot apertures 610 are elongated openings extending through the shield material and are configured to function as frequency-selective elements that attenuate electromagnetic energy at one or more targeted electromagnetic interference frequencies, as described previously with reference to the frequency-selective region and the U-shaped slots.

With continued reference to FIG. 6, a retention lance 634 is formed from material of the outer conductive spatial shield 602 and extends inwardly from the side wall. The retention lance 634 is configured to mechanically engage a corresponding feature of the internal connector housing, thereby securing the outer conductive spatial shield 602 relative to the connector. The retention lance 634 may maintain the positional relationship between the outer conductive spatial shield 602 and the connector housing during operation and connector mating cycles.

The shielded connector assembly 600 includes a folded hem 608 along a lower perimeter of the outer conductive spatial shield 602. The folded hem 608 comprises a turned or doubled-over edge of the conductive material. The folded hem 608 provides structural stiffness and enhanced solder-wicking capability when mounted to a printed circuit board. The folded hem 608 may also provide improved handling safety during assembly. In some cases, the outer conductive spatial shield 602 may include embossed edges or folded flanges to stiffen the shield around the slot openings formed by the slot apertures 610.

As further shown in FIG. 6, bottom locating feet 606 extend downward from a lower flange region of the outer conductive spatial shield 602. The bottom locating feet 606 are configured to position the shielded connector assembly 600 relative to a printed circuit board, establish a consistent stand-off height, and assist in alignment prior to soldering. The bottom locating feet 606 may engage corresponding apertures or features in the printed circuit board to ensure proper positioning of the shielded connector assembly 600 during assembly.

The outer conductive spatial shield 602 may be fabricated using metal stamping to form the slot pattern and tab cutouts. In some cases, the outer conductive spatial shield 602 may be fabricated using laser cutting to form the slot pattern and tab cutouts before bending into shape. The fabrication process may form a flat sheet of conductive material with the slot apertures 610 and other features, which is then bent into shape to form the connector shell structure.

In combination, the top wall 604, the slot array 612 formed by the slot apertures 610, the retention lance 634, the folded hem 608, the corner edge 620, and the bottom locating feet 606 define a mechanically robust and electromagnetically controlled shield structure configured for stable printed circuit board mounting and enhanced electromagnetic interference and desense mitigation. The slot array 612 provides targeted electromagnetic attenuation while maintaining mechanical integrity, and the folded hem 608 provides structural stiffness and enhanced solder-wicking capability when the shielded connector assembly 600 is mounted to a printed circuit board.

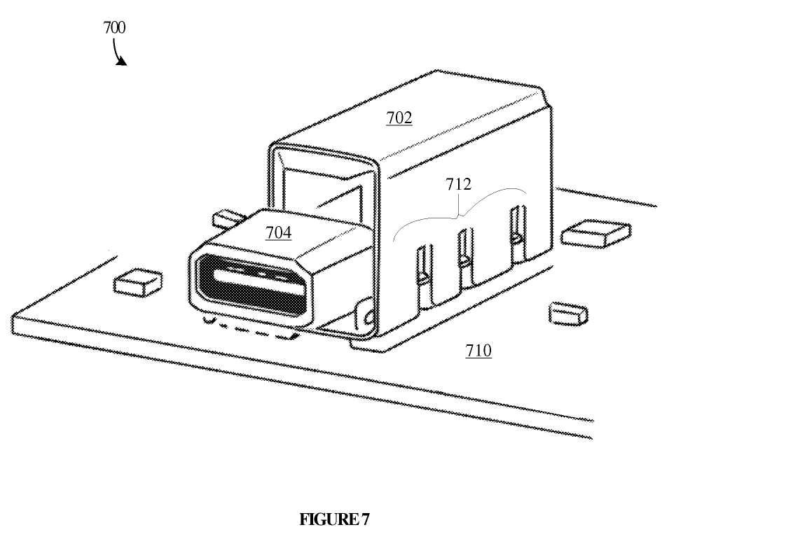

Referring to FIG. 7, a printed circuit board assembly 700 includes a shielded high-speed connector mounted to a printed circuit board 710. The printed circuit board assembly 700 comprises a high-speed connector 702 mechanically and electrically mounted to the printed circuit board 710. The printed circuit board 710 includes a ground plane to which the outer conductive spatial shield of the high-speed connector 702 may be electrically connected. The high-speed connector 702 includes a high-speed connector housing mounted to the printed circuit board 710 and including a plurality of electrical terminals, as described previously with reference to the electrical terminals 132.

The high-speed connector 702 includes an outer conductive spatial shield at least partially surrounding the high-speed connector housing and defining a mating interface 704 accessible from an edge of the printed circuit board 710. The mating interface 704 enables external device coupling while the outer conductive spatial shield provides electromagnetic containment around the high-speed connector housing. The high-speed connector housing may comprise a connector selected from the group consisting of a Universal Serial Bus connector, an HDMI connector, a DisplayPort connector, a PCI Express connector, a MIPI interface connector, and a Thunderbolt connector.

With continued reference to FIG. 7, a slot array 712 is formed in a side wall of the outer conductive spatial shield of the high-speed connector 702. The slot array 712 comprises a plurality of slot apertures arranged in a patterned configuration. The slot array 712 is dimensioned to attenuate electromagnetic energy at one or more predetermined electromagnetic interference frequencies while maintaining structural integrity and electrical grounding of the outer conductive spatial shield. The slot apertures of the slot array 712 function as frequency-selective elements that produce resonant attenuation at the targeted electromagnetic interference frequencies, as described previously with reference to the frequency-selective region 300 and the U-shaped slots 302.

The outer conductive spatial shield of the high-speed connector 702 includes a bottom flange continuously soldered to the ground plane of the printed circuit board 710 to establish a substantially continuous, low-impedance ground path for the outer conductive spatial shield, as described previously. The slot array 712 and the substantially continuous, low-impedance ground path cooperate to suppress electromagnetic interference within the printed circuit board assembly 700. Common-mode currents induced on the outer conductive spatial shield may be shunted to the ground plane through the substantially continuous, low-impedance ground path while electromagnetic energy at the predetermined electromagnetic interference frequencies is attenuated by the slot array 712.

As further shown in FIG. 7, the printed circuit board 710 supports the high-speed connector 702 through soldered terminals and shield grounding features. In the illustrated configuration, the high-speed connector 702 is positioned adjacent to an edge of the printed circuit board 710, enabling external device coupling through the mating interface 704 while the outer conductive spatial shield suppresses radiated emissions and mitigates desense effects within the surrounding electronic system. The printed circuit board assembly 700 depicts system-level integration of the high-speed connector 702 onto the printed circuit board 710, illustrating how the slot array 712 operates in an installed configuration to provide enhanced electromagnetic compatibility performance.

The slot array 712 may be positioned on a top surface of the outer conductive spatial shield in addition to or instead of the side walls. In some cases, the slot apertures of the slot array 712 may be formed in both the top wall and the side walls of the outer conductive spatial shield to provide frequency-selective filtering across multiple surfaces of the shield structure. The positioning of the slot array 712 may be selected based on the orientation of the high-speed connector 702 relative to nearby wireless receivers and the predominant radiation paths for electromagnetic interference.

The slot apertures of the slot array 712 may function to provide ventilation and heat dissipation through the shielded connector assembly in addition to frequency-selective filtering. The slot apertures may permit airflow through the outer conductive spatial shield, which may help cool the high-speed connector 702 or adjacent components on the printed circuit board 710. In some cases, high-speed connectors may generate heat during operation, and the slot apertures may provide a path for convective cooling while simultaneously providing the frequency-selective filtering function described previously. The slot apertures may be dimensioned to permit airflow while remaining electromagnetically small at frequencies outside the targeted resonance band, thereby maintaining broadband shielding effectiveness while providing both thermal management and frequency-selective EMI attenuation.

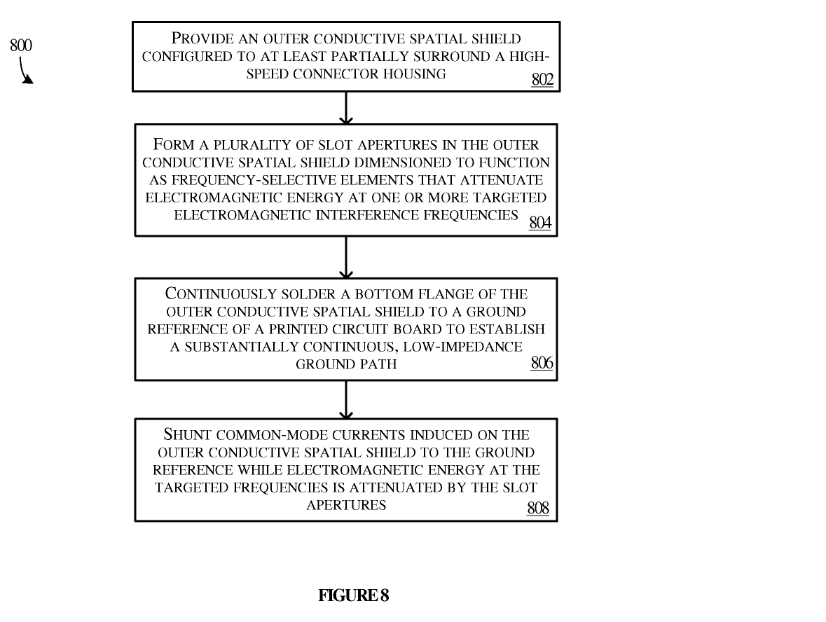

Referring to FIG. 8, a method 800 of mitigating electromagnetic interference in a high-speed connector is illustrated in flowchart form. The method 800 includes a sequence of operations for integrating frequency-selective filtering with continuous grounding to achieve electromagnetic interference mitigation in high-speed connector applications. The method 800 demonstrates how the slot apertures and the substantially continuous, low-impedance ground path cooperate to suppress electromagnetic interference within a high-speed connector assembly.

The method 800 begins with a step 802, where an outer conductive spatial shield configured to at least partially surround a high-speed connector housing is provided. As described previously, the outer conductive spatial shield may be formed of conductive material such as stamped sheet metal including copper alloy, brass, or stainless steel. The outer conductive spatial shield may define an interior cavity sized to receive the high-speed connector housing and may include a top wall and at least one side wall that together provide electromagnetic containment around the high-speed connector housing. In some cases, the outer conductive spatial shield may be a one-piece wraparound shield, while in other cases the outer conductive spatial shield may comprise multiple pieces that assemble around the high-speed connector housing.

With continued reference to FIG. 8, the method 800 proceeds to a step 804, where a plurality of slot apertures are formed in the outer conductive spatial shield. The plurality of slot apertures are dimensioned to function as frequency-selective elements that attenuate electromagnetic energy at one or more targeted electromagnetic interference frequencies. As described previously with reference to the frequency-selective region 300 and the U-shaped slots 302, the slot apertures may be characterized by geometric parameters including slot length, slot width, and center-to-center spacing. The slot length may be selected to produce electromagnetic resonance at the one or more targeted electromagnetic interference frequencies, with the slot length corresponding to a fraction of a wavelength of the targeted frequencies. In some cases, the slot apertures may be formed by stamping or laser cutting the conductive material of the outer conductive spatial shield.

Following step 804, the method 800 moves to a step 806, where a bottom flange of the outer conductive spatial shield is continuously soldered to a ground reference of a printed circuit board to establish a substantially continuous, low-impedance ground path. As described previously with reference to the bottom flange 136, the continuous soldering approach may form a metallurgical bond between the bottom flange and ground pads of the printed circuit board during a reflow soldering process. The substantially continuous, low-impedance ground path may minimize impedance variation along the interface between the outer conductive spatial shield and the printed circuit board, thereby suppressing formation of resonant leakage paths at frequencies above 1 GHz. The continuous soldering step may be performed such that solder substantially bridges adjacent portions of the bottom flange, thereby reducing high-frequency impedance variation.

As further shown in FIG. 8, the method 800 concludes with a step 808, where common-mode currents induced on the outer conductive spatial shield are shunted to the ground reference while electromagnetic energy at the targeted electromagnetic interference frequencies is attenuated by the slot apertures. The substantially continuous, low-impedance ground path established in step 806 provides a preferential path for common-mode currents to flow to the ground reference rather than radiating as electromagnetic interference. Simultaneously, the slot apertures formed in step 804 produce resonant attenuation of electromagnetic energy at the one or more targeted electromagnetic interference frequencies. The combination of common-mode current shunting through the low-impedance ground path and frequency-selective attenuation through the slot apertures provides comprehensive electromagnetic interference mitigation that addresses both broadband noise mechanisms and frequency-specific interference.

The method 800 illustrates the sequential relationship between providing the outer conductive spatial shield, forming the frequency-selective slot apertures, establishing the continuous ground connection through soldering, and achieving the combined electromagnetic interference mitigation through both grounding and frequency-selective filtering. In some cases, the one or more targeted electromagnetic interference frequencies may comprise frequencies between approximately 2.4 GHz and 6 GHz, which may correspond to frequency bands used by wireless communication systems such as Wi-Fi and Bluetooth. In some cases, the method 800 may reduce radiated electromagnetic interference by at least 10 dB at the one or more targeted electromagnetic interference frequencies while simultaneously improving wireless receiver sensitivity by reducing desense effects within the surrounding electronic system.

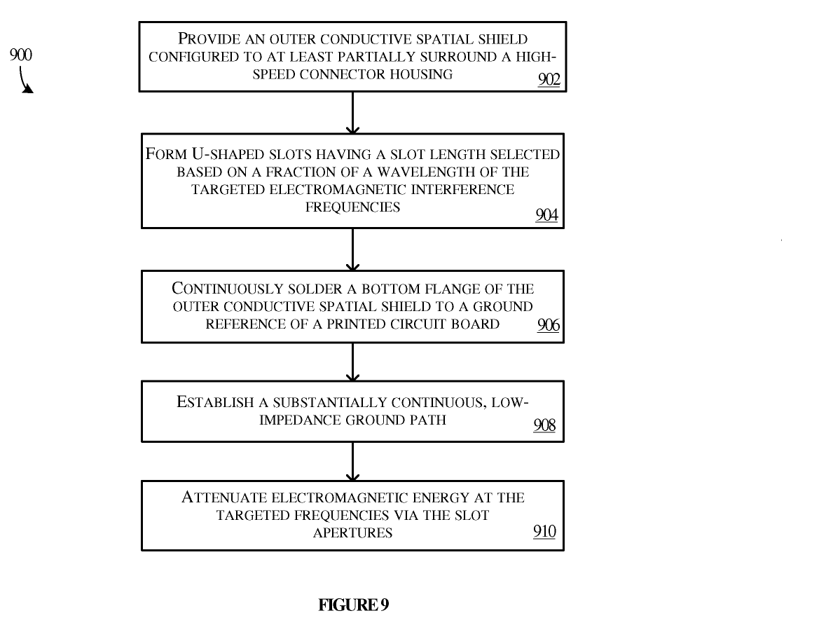

Referring to FIG. 9, a method 900 of mitigating electromagnetic interference in a high-speed connector is illustrated in flowchart form. The method 900 includes a sequence of operations for integrating frequency-selective filtering using U-shaped slots with continuous grounding to achieve electromagnetic interference mitigation in high-speed connector applications. The method 900 demonstrates how U-shaped slots having dimensions corresponding to targeted interference wavelengths cooperate with low-impedance grounding to suppress electromagnetic interference within a high-speed connector assembly.

The method 900 begins with a step 902, where an outer conductive spatial shield configured to at least partially surround a high-speed connector housing is provided. As described previously, the outer conductive spatial shield may be formed of conductive material such as stamped sheet metal including copper alloy, brass, or stainless steel. The outer conductive spatial shield may define an interior cavity sized to receive the high-speed connector housing and may include a top wall and at least one side wall that together provide electromagnetic containment around the high-speed connector housing.

With continued reference to FIG. 9, the method 900 proceeds to a step 904, where U-shaped slots having a slot length selected based on a fraction of a wavelength of the targeted electromagnetic interference frequencies are formed. As described previously with reference to the frequency-selective region 300 and the U-shaped slots 302, each U-shaped slot may be characterized by geometric parameters including a slot length (L), a slot width (W), and a center-to-center spacing (S) relative to adjacent slot apertures. The slot length (L) may be selected to produce electromagnetic resonance at the one or more targeted electromagnetic interference frequencies, with the slot length corresponding to a fraction of a wavelength of the targeted frequencies. In some cases, the slot length may be approximately 50-60 mm to target the 2.4 GHz frequency band, while in other cases the slot length may be approximately 25 mm to target the 5 GHz frequency band.

Following step 904, the method 900 moves to a step 906, where a bottom flange of the outer conductive spatial shield is continuously soldered to a ground reference of a printed circuit board. As described previously with reference to the bottom flange 136, the continuous soldering approach may form a metallurgical bond between the bottom flange and ground pads of the printed circuit board during a reflow soldering process.

As further shown in FIG. 9, the method 900 continues to a step 908, where a substantially continuous, low-impedance ground path is established. The substantially continuous, low-impedance ground path may minimize impedance variation along the interface between the outer conductive spatial shield and the printed circuit board, thereby suppressing formation of resonant leakage paths at frequencies above 1 GHz. Common-mode currents induced on the outer conductive spatial shield may be preferentially shunted to the ground reference through the substantially continuous, low-impedance ground path rather than radiating as electromagnetic interference.

The method 900 concludes with a step 910, where electromagnetic energy at the targeted frequencies is attenuated via the slot apertures. The U-shaped slots formed in step 904 produce resonant attenuation of electromagnetic energy at the one or more targeted electromagnetic interference frequencies. The slot length selected based on a fraction of a wavelength of the targeted electromagnetic interference frequencies causes the U-shaped slots to exhibit resonant behavior at those frequencies, producing a frequency-selective response characterized by a notch in shielding effectiveness at the targeted frequencies. Outside of the resonance band, the outer conductive spatial shield continues to function as a substantially continuous conductive barrier that blocks electromagnetic interference at other frequencies.

The method 900 combines frequency-selective filtering through the dimensioned U-shaped slots with low-impedance grounding to shunt common-mode currents while attenuating electromagnetic energy at the targeted electromagnetic interference frequencies. The forming of the plurality of slot apertures comprises forming U-shaped slots having a slot length selected based on a fraction of a wavelength of the one or more targeted electromagnetic interference frequencies, as described previously. In some cases, the one or more targeted electromagnetic interference frequencies may comprise frequencies between approximately 2.4 GHz and 6 GHz, which may correspond to frequency bands used by wireless communication systems such as Wi-Fi and Bluetooth that are susceptible to interference from high-speed connectors.

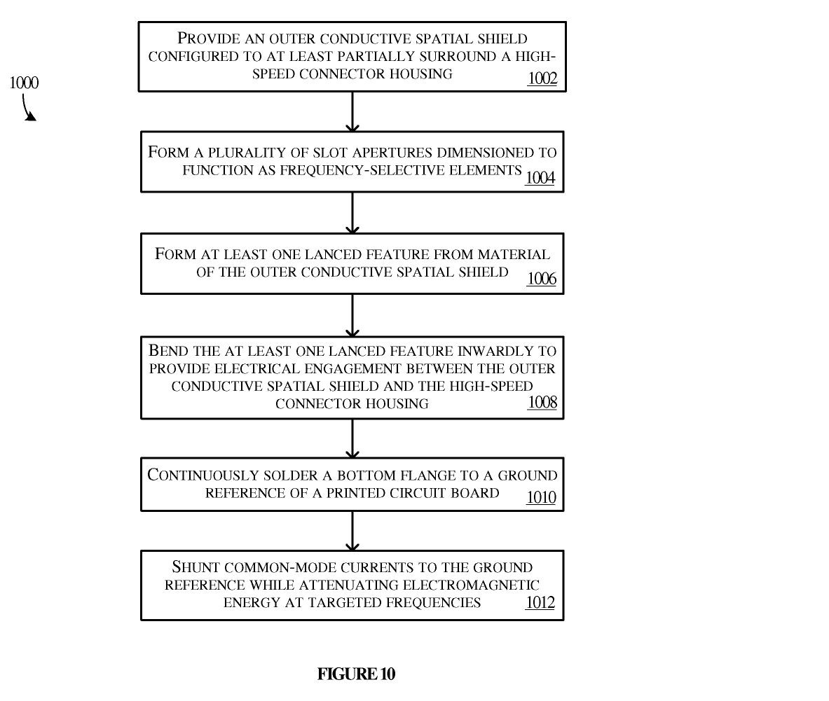

Referring to FIG. 10, a method 1000 of mitigating electromagnetic interference in a high-speed connector is illustrated in flowchart form. The method 1000 includes a sequence of operations for integrating frequency-selective filtering with lanced features and continuous grounding to achieve electromagnetic interference mitigation in high-speed connector applications. The method 1000 demonstrates how the slot apertures, the lanced features, and the substantially continuous, low-impedance ground path cooperate to suppress electromagnetic interference within a high-speed connector assembly.

The method 1000 begins with a step 1002, where an outer conductive spatial shield configured to at least partially surround a high-speed connector housing is provided. As described previously, the outer conductive spatial shield may be formed of conductive material such as stamped sheet metal including copper alloy, brass, or stainless steel. The outer conductive spatial shield may define an interior cavity sized to receive the high-speed connector housing and may include a top wall and at least one side wall that together provide electromagnetic containment around the high-speed connector housing. In some cases, the outer conductive spatial shield may be a one-piece wraparound shield, while in other cases the outer conductive spatial shield may comprise multiple pieces that assemble around the high-speed connector housing.

With continued reference to FIG. 10, the method 1000 proceeds to a step 1004, where a plurality of slot apertures dimensioned to function as frequency-selective elements are formed in the outer conductive spatial shield. As described previously with reference to the frequency-selective region 300 and the U-shaped slots 302, the slot apertures may be characterized by geometric parameters including slot length, slot width, and center-to-center spacing. The slot apertures are dimensioned such that at least one geometric parameter corresponds to a fraction of a wavelength of one or more targeted electromagnetic interference frequencies, whereby the slot apertures function as frequency-selective elements that attenuate electromagnetic energy at the one or more targeted electromagnetic interference frequencies. In some cases, the slot apertures may be formed by stamping or laser cutting the conductive material of the outer conductive spatial shield.

Following step 1004, the method 1000 moves to a step 1006, where at least one lanced feature is formed from material of the outer conductive spatial shield. As described previously with reference to the lanced feature 116, the lanced feature may be formed by partial stamping (lancing) of the shield material. The lanced feature may be associated with a slot aperture and may be formed from the material removed or displaced during formation of the slot aperture. In some cases, each slot aperture may include an associated lanced feature formed from the material of the outer conductive spatial shield.

As further shown in FIG. 10, the method 1000 continues to a step 1008, where the at least one lanced feature is bent inwardly to provide electrical engagement between the outer conductive spatial shield and the high-speed connector housing. The lanced feature may be bent inwardly into the interior cavity toward the high-speed connector housing to establish electrical contact between the outer conductive spatial shield and the high-speed connector housing disposed within the interior cavity. In some cases, the lanced feature may cooperate with the resilient grounding tab to maintain a low-impedance electrical connection between the outer conductive spatial shield and the high-speed connector housing, as described previously. The electrical engagement provided by the lanced feature may reduce impedance discontinuities and may suppress common-mode noise that could otherwise radiate from the connector structure.

The method 1000 then advances to a step 1010, where a bottom flange of the outer conductive spatial shield is continuously soldered to a ground reference of a printed circuit board to establish a substantially continuous, low-impedance ground path. As described previously with reference to the bottom flange 136, the continuous soldering approach may form a metallurgical bond between the bottom flange and ground pads of the printed circuit board during a reflow soldering process. The substantially continuous, low-impedance ground path may minimize impedance variation along the interface between the outer conductive spatial shield and the printed circuit board, thereby suppressing formation of resonant leakage paths at frequencies above 1 GHz.

The method 1000 concludes with a step 1012, where common-mode currents induced on the outer conductive spatial shield are shunted to the ground reference while electromagnetic energy at targeted electromagnetic interference frequencies is attenuated by the slot apertures. The substantially continuous, low-impedance ground path established in step 1010 provides a preferential path for common-mode currents to flow to the ground reference rather than radiating as electromagnetic interference. Simultaneously, the slot apertures formed in step 1004 produce resonant attenuation of electromagnetic energy at the one or more targeted electromagnetic interference frequencies. The electrical engagement between the outer conductive spatial shield and the high-speed connector housing established by the lanced feature in step 1008 may further reduce common-mode noise by providing additional low-impedance electrical connections between the outer conductive spatial shield and the high-speed connector housing.

The method 1000 illustrates the sequence of operations for integrating frequency-selective filtering with continuous grounding and lanced features to achieve electromagnetic interference mitigation in high-speed connector applications. The forming of at least one lanced feature from material of the outer conductive spatial shield and bending the at least one lanced feature inwardly to provide electrical engagement between the outer conductive spatial shield and the high-speed connector housing, as described in steps 1006 and 1008, may enhance the electromagnetic interference mitigation by establishing multiple points of electrical contact between the outer conductive spatial shield and the high-speed connector housing. In some cases, the one or more targeted electromagnetic interference frequencies may comprise frequencies between approximately 2.4 GHz and 6 GHz, which may correspond to frequency bands used by wireless communication systems such as Wi-Fi and Bluetooth that are susceptible to interference from high-speed connectors.

A number of implementations have been described. Nevertheless, it will be understood that various modifications may be made without departing from the spirit and scope of the disclosure. Accordingly, other implementations are within the scope of the following claims.

1. A shielded connector assembly, comprising:
a high-speed connector housing;
an outer conductive spatial shield formed of conductive material and configured to at least partially surround the high-speed connector housing, the outer conductive spatial shield including a top wall and at least one side wall defining an interior cavity;
a plurality of slot apertures formed in the at least one side wall of the outer conductive spatial shield, the plurality of slot apertures arranged in a slot array and dimensioned such that at least one geometric parameter corresponds to a fraction of a wavelength of one or more targeted electromagnetic interference frequencies, whereby the slot array functions as a frequency-selective structure that attenuates electromagnetic energy at the one or more targeted electromagnetic interference frequencies; and
at least one lanced feature formed from material of the outer conductive spatial shield and extending into the interior cavity, the at least one lanced feature configured to provide electrical engagement between the outer conductive spatial shield and the high-speed connector housing disposed within the interior cavity.

2. The shielded connector assembly of claim 1, wherein each slot aperture comprises a U-shaped slot having: a slot length (L), a slot width (W), and a center-to-center spacing (S) relative to adjacent slot apertures.

3. The shielded connector assembly of claim 2, wherein the slot length (L) is selected to produce electromagnetic resonance at the one or more targeted electromagnetic interference frequencies.

4. The shielded connector assembly of claim 1, further comprising:
a metal web disposed between adjacent slot apertures, the metal web providing structural rigidity and an uninterrupted conductive path outside of a resonance band associated with the one or more targeted electromagnetic interference frequencies.

5. The shielded connector assembly of claim 1, further comprising a resilient grounding tab extending from a mating wall of the outer conductive spatial shield and configured to maintain electrical contact with a conductive surface of the high-speed connector housing.

6. The shielded connector assembly of claim 5, wherein the at least one lanced feature cooperates with the resilient grounding tab to maintain a low-impedance electrical connection between the outer conductive spatial shield and the high-speed connector housing.

7. The shielded connector assembly of claim 1, further comprising a retention lance formed from material of the outer conductive spatial shield and configured to mechanically secure the outer conductive spatial shield relative to the high-speed connector housing.

8. The shielded connector assembly of claim 1, further comprising a folded hem along a lower perimeter of the outer conductive spatial shield, the folded hem providing structural stiffness and enhanced solder-wicking capability when mounted to a printed circuit board.

9. The shielded connector assembly of claim 1, further comprising a bottom flange extending along a lower edge of the outer conductive spatial shield and configured for mechanical and electrical attachment to a printed circuit board.

10. The shielded connector assembly of claim 9, further comprising at least one alignment feature extending downward from the bottom flange and configured to position the shielded connector assembly relative to a printed circuit board.

11. A shielded connector assembly, comprising:
a high-speed connector housing;
an outer conductive spatial shield formed of conductive material and configured to at least partially surround the high-speed connector housing;
a plurality of slot apertures formed in the outer conductive spatial shield and arranged in a slot array dimensioned to function as a frequency-selective structure that attenuates electromagnetic energy at one or more targeted electromagnetic interference frequencies; and
a bottom flange extending along a lower perimeter of the outer conductive spatial shield, the bottom flange configured to be continuously soldered to a ground reference of a printed circuit board to establish a substantially continuous, low-impedance electrical ground path around at least a portion of the outer conductive spatial shield,
wherein common-mode currents induced on the outer conductive spatial shield are preferentially shunted to the ground reference through the substantially continuous, low-impedance electrical ground path while the slot array attenuates electromagnetic energy at the one or more targeted electromagnetic interference frequencies.

12. The shielded connector assembly of claim 11, wherein the bottom flange is configured to form a metallurgical bond to ground pads of the printed circuit board during a reflow soldering process.

13. The shielded connector assembly of claim 11, wherein impedance variation along an interface between the bottom flange and the printed circuit board is minimized to suppress formation of resonant leakage paths at frequencies above 1 GHz.

14. The shielded connector assembly of claim 11, wherein each slot aperture comprises a U-shaped slot having a slot length selected based on a fraction of a wavelength of the one or more targeted electromagnetic interference frequencies.

15. The shielded connector assembly of claim 11, wherein the slot array is configured to produce a frequency-selective response characterized by a notch in shielding effectiveness at a notch frequency corresponding to an engineered resonance of the slot array.

16. The shielded connector assembly of claim 11, wherein the one or more targeted electromagnetic interference frequencies comprise frequencies between approximately 2.4 GHz and 6 GHz.

17. The shielded connector assembly of claim 11, wherein the high-speed connector housing comprises a connector selected from the group consisting of:
a Universal Serial Bus connector,
an HDMI connector,
a DisplayPort connector,
a PCI Express connector, and
a MIPI interface connector.

18. A printed circuit board assembly, comprising:
a printed circuit board including a ground plane;
a high-speed connector housing mounted to the printed circuit board and including a plurality of electrical terminals; and
an outer conductive spatial shield at least partially surrounding the high-speed connector housing, the outer conductive spatial shield including:
a plurality of slot apertures arranged in a slot array dimensioned to attenuate electromagnetic energy at one or more predetermined electromagnetic interference frequencies; and
a bottom flange continuously soldered to the ground plane of the printed circuit board to establish a substantially continuous, low-impedance ground path for the outer conductive spatial shield,
wherein the slot array and the substantially continuous, low-impedance ground path cooperate to suppress electromagnetic interference within the printed circuit board assembly.

19. The printed circuit board assembly of claim 18, wherein each slot aperture comprises a U-shaped slot having a slot length selected to produce electromagnetic resonance at the one or more predetermined electromagnetic interference frequencies.

20. The printed circuit board assembly of claim 18, wherein a metal web is disposed between adjacent slot apertures to provide structural rigidity and an uninterrupted conductive path outside of a resonance band associated with the one or more predetermined electromagnetic interference frequencies.

21. A method of mitigating electromagnetic interference in a high-speed connector, the method comprising:
providing an outer conductive spatial shield configured to at least partially surround a high-speed connector housing;
forming a plurality of slot apertures in the outer conductive spatial shield, the plurality of slot apertures dimensioned to function as frequency-selective elements that attenuate electromagnetic energy at one or more targeted electromagnetic interference frequencies; and
continuously soldering a bottom flange of the outer conductive spatial shield to a ground reference of a printed circuit board to establish a substantially continuous, low-impedance ground path,
whereby common-mode currents induced on the outer conductive spatial shield are shunted to the ground reference while electromagnetic energy at the one or more targeted electromagnetic interference frequencies is attenuated by the slot apertures.

22. The method of claim 21, wherein forming the plurality of slot apertures comprises forming U-shaped slots having a slot length selected based on a fraction of a wavelength of the one or more targeted electromagnetic interference frequencies.

23. The method of claim 21, further comprising forming at least one lanced feature from material of the outer conductive spatial shield and bending the at least one lanced feature inwardly to provide electrical engagement between the outer conductive spatial shield and the high-speed connector housing.
